(19) United States
(12) Patent Application Publication
(10) Pub. No.: US 2021/0344215 A1
(43) Pub. Date: Nov. 4, 2021

(54) Power Saving Modes for Subsystems in Solar Powered Aircraft

(71) Applicant: LOON LLC, Mountain View, CA (US)

(72) Inventors: Sailesh Prabhu, Mountain View, CA (US); Jean-Laurent Plateau, Mountain View, CA (US); Nidhi Gulia, Mountain View, CA (US); Benjamin Wojtowicz, Mountain View, CA (US)

(73) Assignee: LOON LLC, Mountain View, CA (US)

(21) Appl. No.: 16/863,883

(22) Filed: Apr. 30, 2020

(51) Int. Cl. H02J 7/35; B64C 19/00; H02J 7/00; G06F 30/34

(52) U.S. Cl. CPC H02J 7/35; B64C 19/00; H02J 2300/24; G06F 30/34; H02J 7/0068

(57) ABSTRACT

The technology relates to power saving modes for subsystems in solar powered aircraft. An onboard subsystem of an aircraft includes a first processor configured to monitor a state of the subsystem and generate state data; a heating component configured to heat the subsystem to at least a minimum viable temperature; an operational component; and a hardware controller configured to control power to the heating component, the first processor, and the operational component, at least during a preservation mode and a monitoring mode. The subsystem draws a moderate amount of power when the heating component is on and a minimum threshold amount of power in the preservation mode. The subsystem draws a moderate amount of power in the monitoring mode in order to generate and communicate state data by the first processor, a moderate amount of power being lower than the higher amount of power required to operate the operational component.

### BACKGROUND OF INVENTION

Many aircraft that remain afloat or in-flight for long periods of time (e.g., high altitude aircraft) rely on solar, wind, or other renewable sources of, power to operate onboard subsystems. In order to do so, the aircraft may collect energy in batteries, or other energy storage solutions, during times when the energy source (e.g., sun, wind) is available, and then rely on the stored energy when the energy source is not available.

In solar powered aircraft, power may be collected and stored in batteries during the day (i.e., sunrise to sunset), and then the aircraft may run solely on battery power at night (i.e., sunset to sunrise). For aircraft that remain in-flight for multiple days, weeks, months or even years, it is critical to manage power consumption during nighttime flight to ensure the aircraft does not lose power before sunrise. Where the aircraft needs to not only power its flight, but also power and maintain the health of components (i.e., subsystems) to provide services, such as data and network connectivity, surveillance and other types of data gathering (e.g., image capture, audio and video recording, weather and environmental data, telemetry), it is often not possible or practical to power all of these subsystems continuously. Conventional techniques of powering off subsystems can be damaging to such subsystems when the environment is too cold. Such “cold soaking” of hardware components in extremely cold environments (e.g., high altitudes above Earth's surface, such as the stratosphere or beyond) can damage the hardware components irrevocably. Thus, it is crucial to enable monitoring and minimum health maintenance functions while minimizing power usage.

Thus, there is a need for efficient power saving modes for subsystems in solar powered aircraft.

### BRIEF SUMMARY

The present disclosure provides for techniques relating to power saving modes for subsystems in solar powered aircraft. An onboard subsystem of an aircraft includes a first processor configured to monitor a state of the subsystem and generate state data; a heating component configured to heat the subsystem to at least a minimum viable temperature; an operational component; and a hardware controller configured to control power to the heating component, the first processor, and the operational component, at least during a preservation mode and a monitoring mode, wherein the subsystem draws a first moderate amount of power when the heating component is on and a minimum threshold amount of power in the preservation mode, wherein the subsystem draws a second moderate amount of power in the monitoring mode in order to generate and communicate state data by the first processor, and wherein the first and second moderate amounts of power are lower than a high amount of power required to operate the operational component.

In some examples, the subsystem comprises a communications unit. In some examples, the communications unit comprises an LTE eNodeB. In some examples, the first processor comprises a high-level FPGA. In some examples, the onboard subsystem also includes a second processor configured to implement a software stack. In some examples, the operational component comprises a radio head configured to transmit and receive radio waves. In some examples, the first processor and the hardware controller are implemented as a system on chip. In some examples, the hardware controller is configured to receive a command from the first processor to control power to the first processor during the preservation mode. In some examples, the hardware logic is configured to monitor a temperature sensor in the preservation mode. In some examples, the hardware logic is configured to power on the heating component to the first moderate amount of power in response to a temperature sensor reading below a minimum viable threshold temperature. In some examples, the minimum threshold amount of power is within a range of 3 W-30 W. In some examples, the first moderate amount of power and the second moderate amount of power are both within a range of 20 W-100 W, the first moderate amount of power being higher than the second moderate amount of power.

A method for implementing one or more power saving modes in a communication subsystem of a solar-powered aircraft includes receiving, by a hardware controller, a command to enter a preservation mode; entering the preservation mode by powering off, by the hardware controller, a processor and an operational component of the communication subsystem; maintaining a minimum threshold amount of power to the communication subsystem during the preservation mode; powering on, by the hardware controller, a heating component after a first time period; powering off, by the hardware controller, a heating component after a second time period; powering on, by the hardware controller, the processor after a third time period to enter a monitoring mode, the processor configured to monitor a state of the communication subsystem and generate state data while in the monitoring mode; and powering on, by the hardware controller, the processor and the operational component after a fourth time period to return to an operational mode.

In some examples, the first period of time, the second period of time, and the third period of time, are predetermined. In some examples, powering on the heating component occurs in response to a temperature sensor measuring below a minimum viable threshold temperature, the temperature sensor configured to measure a temperature of a circuit board on which the processor and the hardware controller are implemented. In some examples, powering off the heating component occurs in response to a temperature sensor registering above a higher threshold temperature, the temperature sensor configured to measure a temperature of a circuit board on which the processor and the hardware controller are implemented. In some examples, the state data generated in the monitoring mode comprises sensor data. In some examples, the state data generated in the monitoring mode comprises a time elapsed in the preservation mode. In some examples, the state data generated in the monitoring mode comprises a time elapsed since the processor last broadcasted a set of state data in the monitoring mode. In some examples, the state data generated in the monitoring mode comprises a time elapsed since a last sunset. In some examples, the state data comprises a next expected sunrise time. In some examples, the operational component comprises a radio head configured to transmit and receive radio waves. In some examples, the communication subsystem is a non-flight critical component of the solar-powered aircraft. In some examples, receiving the command to enter the preservation mode occurs shortly before, at, or after, a sunset. In some examples, powering on the processor and the operational component after a fourth period of time to return to an operational mode occurs after a sunrise.

### BRIEF DESCRIPTION OF THE DRAWINGS

FIGS. 1A-1B are diagrams of exemplary solar-powered aircraft systems with subsystems, in accordance with one or more embodiments;

FIG. 2 is a simplified block diagram of an exemplary computing system forming part of the systems of FIGS. 1A-2, in accordance with one or more embodiments;

FIG. 3 is a simplified block diagram of an exemplary communications unit implemented onboard an aircraft, in accordance with one or more embodiments;

FIG. 4 is a simplified block diagram of an exemplary network comprising an exemplary communications unit, in accordance with one or more embodiments;

FIG. 5 is a chart showing exemplary power provided to a communication subsystem of a solar-powered aircraft in several power modes, in accordance with one or more embodiments; and

FIG. 6 is a flow diagram illustrating a method for implementing one or more power saving modes in a communication subsystem of a solar-powered aircraft, in accordance with one or more embodiments.

The figures depict various example embodiments of the present disclosure for purposes of illustration only. One of ordinary skill in the art will readily recognize from the following discussion that other example embodiments based on alternative structures and methods may be implemented without departing from the principles of this disclosure, and which are encompassed within the scope of this disclosure.

### DETAILED DESCRIPTION

The Figures and the following description describe certain embodiments by way of illustration only. One of ordinary skill in the art will readily recognize from the following description that alternative embodiments of the structures and methods illustrated herein may be employed without departing from the principles described herein. Reference will now be made in detail to several embodiments, examples of which are illustrated in the accompanying figures.

The above and other needs are met by the disclosed methods, a non-transitory computer-readable storage medium storing executable code, and systems for dispatching fleets of aircraft by a fleet management and flight planning system. The terms “aerial vehicle” and “aircraft” are used interchangeably herein to refer to any type of vehicle capable of aerial movement, including, without limitation, High Altitude Platforms (HAPs), High Altitude Long Endurance (HALE) aircraft, unmanned aerial vehicles (UAVs), passive lighter than air vehicles (e.g., floating stratospheric balloons, other floating or wind-driving vehicles), powered lighter than air vehicles (e.g., balloons and airships with some propulsion capabilities), fixed-wing vehicles (e.g., drones, rigid kites, gliders), various types of satellites, and other high altitude aerial vehicles.

The invention is directed to techniques and systems for managing power consumption by non-flight critical subsystems onboard aerial vehicles, such as LTE units, when said subsystems are not in use. Many aerial vehicles rely on solar power collected between sunrise and sunset to power its onboard systems, and thus between sunset and sunrise, it is important to closely manage the consumption of the power that has been stored in batteries during the day, particularly in wind-driven vehicles, where total mass also is closely managed, the amount of battery capacity carried in a payload may be relatively limited. Thus, it can be important to reduce power consumption by subsystems when not in use, while maintaining minimum health monitoring functions, for example, to maintain a minimum viable temperature.

A subsystem may comprise one or more processors, low-level hardware logic, sub-components that require power, and access to a power source. An example is an LTE unit (eNodeB) implementing an LTE stack and high level FPGA (i.e., processors, including general purpose CPUs, DSPs, and others, as described herein), a low level FPGA (i.e., hardware logic), one or more radio (“RF”) heads configured to transmit and receive radio waves (e.g., to communicate with cellular devices), and access to battery-stored power. The hardware logic may be configured to control power to a heating component configured to heat the subsystem, as well as power to the other components of the subsystem.

In an example method, the hardware logic may be configured to control power to said heater and other components in at least the following modes: a preservation (i.e., low power, aka “idle”) mode, a monitoring (i.e., medium power) mode, and an operational (i.e., high power) mode. In a preservation mode, the hardware logic may be configured to power off other components of the subsystem (e.g., high power consumption components), selectively or entirely, to maintain a minimum power level (e.g., within a range of 3 W-30 W, or more or less) to the subsystem, and to periodically power on the heating component at a low-to-moderate power level for a relatively short period of time (e.g. at approximately 20 W-80 W, or more or less, depending on the heating component and subsystem). In a monitoring mode, the hardware logic may increase power to a moderate power level and wake the high level FPGA to monitor the state of the subsystem, generate state data to communicate with other onboard systems and offboard systems (e.g., LTE network, data center, and the like), and to receive higher level commands from said onboard and offboard systems. The monitoring mode may require a moderate level of power (e.g., approximately 20 W-100 W, or more or less, depending on the particular subsystem) for a period of time (e.g., similar to or longer than an amount of time to heat the subsystem in preservation mode) necessary to gather and transmit some state and/or telemetry data and to receive commands. In operational mode, most or all operating components (e.g., processors and radio heads) are powered, thereby consuming a much higher level of power (e.g., over 100 W) than in preservation or monitoring modes.

In some examples, the selective powering of components in preservation and monitoring modes may be responsive to commands providing predetermined time frames for powering components on and off. In other examples, the selective powering of components in preservation and monitoring modes may be responsive to sensor readings that may be monitored by the hardware logic (e.g., indicating a temperature below a minimum viable temperature or above a higher threshold temperature, indicating a vibration event above a threshold vibration, indicating a sunrise or other energy source availability).

Example Systems

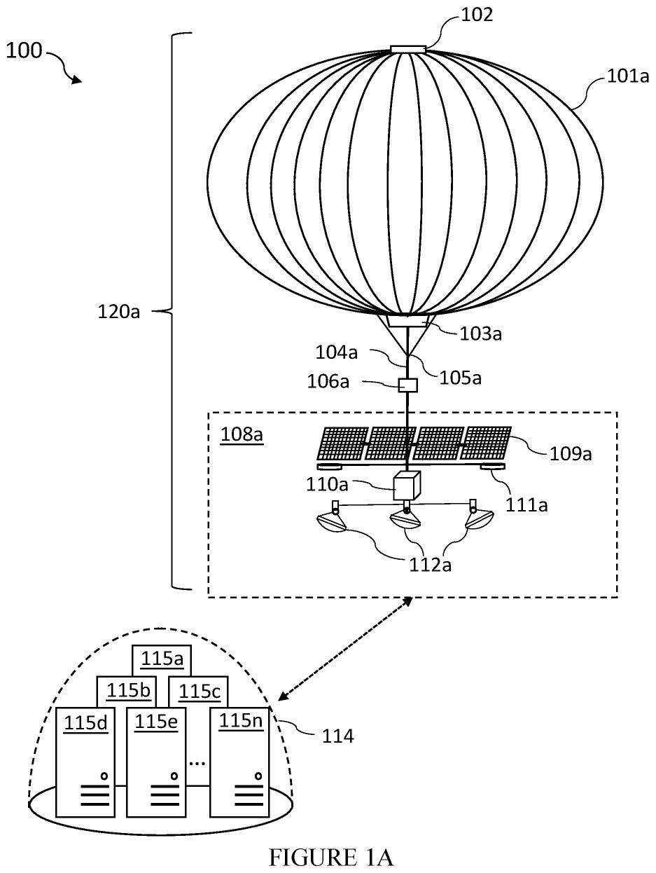

FIGS. 1A-1B are diagrams of exemplary operational systems in which flight policies may be implemented for navigating an aerial vehicle, in accordance with one or more embodiments. In FIG. 1A, there is shown a diagram of system 100 for navigation of aerial vehicle 120a. In some examples, aerial vehicle 120a may be a passive vehicle, such as a balloon or satellite, wherein most of its directional movement is a result of environmental forces, such as wind and gravity. In other examples, aerial vehicles 120a may be actively propelled. In an embodiment, system 100 may include aerial vehicle 120a and ground station 114. In this embodiment, aerial vehicle 120a may include balloon 101a, plate 102, altitude control system (ACS) 103a, connection 104a, joint 105a, actuation module 106a, and payload 108a. In some examples, plate 102 may provide structural and electrical connections and infrastructure. Plate 102 may be positioned at the apex of balloon 101a and may serve to couple together various parts of balloon 101a. In other examples, plate 102 also may include a flight termination unit, such as one or more blades and an actuator to selectively cut a portion and/or a layer of balloon 101a. In other examples, plate 102 further may include other electronic components (e.g., a sensor, a part of a sensor, power source, communications unit). ACS 103a may include structural and electrical connections and infrastructure, including components (e.g., fans, valves, actuators, etc.) used to, for example, add and remove air from balloon 101a (i.e., in some examples, balloon 101a may include an interior ballonet within its outer, more rigid shell that may be inflated and deflated), causing balloon 101a to ascend or descend, for example, to catch stratospheric winds to move in a desired direction. Balloon 101a may comprise a balloon envelope comprised of lightweight and/or flexible latex or rubber materials (e.g., polyethylene, polyethylene terephthalate, chloroprene), tendons (e.g., attached at one end to plate 102 and at another end to ACS 103a) to provide strength and stability to the balloon structure, and a ballonet, along with other structural components. In various embodiments, balloon 101a may be non-rigid, semi-rigid, or rigid.

Connection 104a may structurally, electrically, and communicatively, connect balloon 101a and/or ACS 103a to various components comprising payload 108a. In some examples, connection 104a may provide two-way communication and electrical connections, and even two-way power connections. Connection 104a may include a joint 105a, configured to allow the portion above joint 105a to pivot about one or more axes (e.g., allowing either balloon 101a or payload 108a to tilt and turn). Actuation module 106a may provide a means to actively turn payload 108a for various purposes, such as improved aerodynamics, facing or tilting solar panel(s) 109a advantageously, directing payload 108a and propulsion units (e.g., propellers 107 in FIG. 1B) for propelled flight, or directing components of payload 108a advantageously.

Payload 108a may include solar panel(s) 109a, avionics chassis 110a, broadband communications unit(s) 111a, and terminal(s) 112a. Solar panel(s) 109a may be configured to capture solar energy to be provided to a battery or other energy storage unit, for example, housed within avionics chassis 110a. Avionics chassis 110a also may house a flight computer (e.g., computing device 301, as described herein), a transponder, along with other control and communications infrastructure (e.g., a controller comprising another computing device and/or logic circuit configured to control aerial vehicle 120a). Communications unit(s) 111a may include hardware to provide wireless network access (e.g., LTE, fixed wireless broadband via 5G, Internet of Things (IoT) network, free space optical network or other broadband networks). Terminal(s) 112a may comprise one or more parabolic reflectors (e.g., dishes) coupled to an antenna and a gimbal or pivot mechanism (e.g., including an actuator comprising a motor). Terminal(s) 112(a) may be configured to receive or transmit radio waves to beam data long distances (e.g., using the millimeter wave spectrum or higher frequency radio signals). In some examples, terminal(s) 112a may have very high bandwidth capabilities. Terminal(s) 112a also may be configured to have a large range of pivot motion for precise pointing performance. Terminal(s) 112a also may be made of lightweight materials.

In other examples, payload 108a may include fewer or more components, including propellers 107 as shown in FIG. 1B, which may be configured to propel aerial vehicles 120a-b in a given direction. In still other examples, payload 108a may include still other components well known in the art to be beneficial to flight capabilities of an aerial vehicle. For example, payload 108a also may include energy capturing units apart from solar panel(s) 109a (e.g., rotors or other blades (not shown) configured to be spun, or otherwise actuated, by wind to generate energy). In another example, payload 108a may further include or be coupled to an imaging device, such as a downward-facing camera and/or a star tracker. In yet another example, payload 108a also may include various sensors (not shown), for example, housed within avionics chassis 110a or otherwise coupled to connection 104a or balloon 101a. Such sensors may include Global Positioning System (GPS) sensors, wind speed and direction sensors such as wind vanes and anemometers, temperature sensors such as thermometers and resistance temperature detectors (i.e., RTDs), speed of sound sensors, acoustic sensors, pressure sensors such as barometers and differential pressure sensors, accelerometers, gyroscopes, combination sensor devices such as inertial measurement units (IMUs), light detectors, light detection and ranging (LIDAR) units, radar units, cameras, other image sensors, and more. These examples of sensors are not intended to be limiting, and those skilled in the art will appreciate that other sensors or combinations of sensors in addition to these described may be included without departing from the scope of the present disclosure.

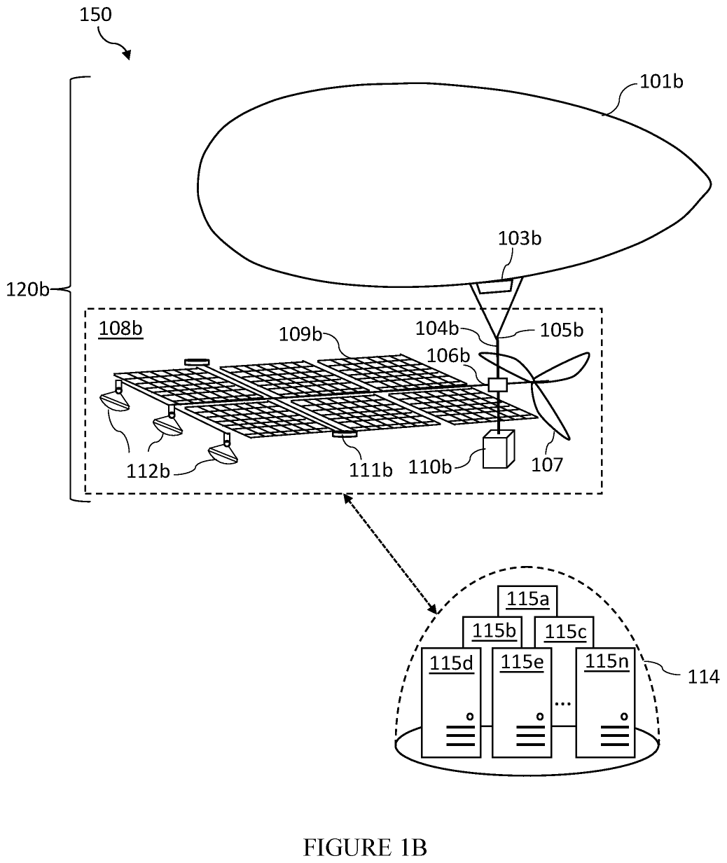

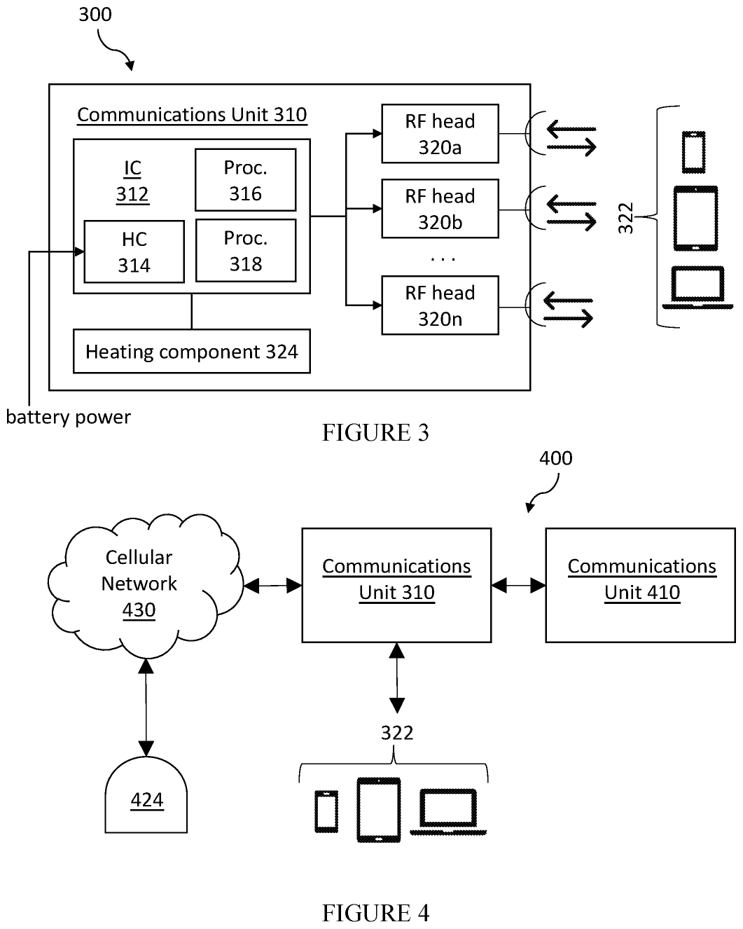

Ground station 114 may include one or more server computing devices 115a-n, which in turn may comprise one or more computing devices (e.g., computing device 201 in FIG. 2). In some examples, ground station 114 also may include one or more storage systems, either housed within server computing devices 115a-n, or separately (see, e.g., computing device 201 and repositories 220). In an example, ground station 114 may be a datacenter servicing various nodes of one or more networks (e.g., network 400 in FIG. 4). In another example, ground station 114 may comprise a terminal (e.g., on a gimbal) on Earth's surface configured to establish an mmWave link with a terminal on an aerial vehicle, as described herein. Ground station 114 may be connected to the Internet.

FIG. 1B shows a diagram of system 150 for navigation of aerial vehicle 120b. All like-numbered elements in FIG. 1B are the same or similar to their corresponding elements in FIG. 1A, as described above (e.g., balloon 101a and balloon 101b may serve the same function, and may operate the same as, or similar to, each other). In some examples, balloon 101b may comprise an airship hull or dirigible balloon. In this embodiment, aerial vehicle 120b further includes, as part of payload 108b, propellers 107, which may be configured to actively propel aerial vehicle 120b in a desired direction, either with or against a wind force to speed up, slow down, or re-direct, aerial vehicle 120b. In this embodiment, balloon 101b also may be shaped differently from balloon 101a, to provide different aerodynamic properties. In some examples, balloon 101b may include one or more fins (not shown) coupled to one or more of a rear, upper, lower, or side, surface (i.e., relative to a direction in which balloon 101b is heading).

As shown in FIGS. 1A-1B, aerial vehicles 120a-b may be largely wind-influenced aerial vehicles, for example, balloons carrying a payload (with or without propulsion capabilities). Techniques described herein also may be implemented in fixed wing high altitude drones (not shown) with gliding and/or full propulsion capabilities. Those skilled in the art will recognize that the systems and methods disclosed herein may similarly apply and be usable by various other types of aerial vehicles.

FIG. 2 is a simplified block diagram of an exemplary computing system forming part of the systems of FIGS. 1A-1B, in accordance with one or more embodiments. In one embodiment, computing system 200 may include computing device 201 and storage system 220. Storage system 220 may comprise a plurality of repositories and/or other forms of data storage, and it also may be in communication with computing device 201. In another embodiment, storage system 220, which may comprise a plurality of repositories, may be housed in one or more of computing device 201 (not shown). In some examples, storage system 320 may store state data, commands, flight policies, and other types of information as described herein. This information may be retrieved or otherwise accessed by one or more computing devices, such as computing device 201 or server computing devices (e.g., 115a-n in FIGS. 1A-1B), in order to perform some or all of the features described herein. Storage system 220 may comprise any type of computer storage, such as a hard-drive, memory card, ROM, RAM, DVD, CD-ROM, write-capable, and read-only memories. In addition, storage system 220 may include a distributed storage system where data is stored on a plurality of different storage devices, which may be physically located at the same or different geographic locations. Storage system 220 may be networked to computing device 201 directly using wired connections and/or wireless connections. Such network may include various configurations and protocols, including short range communication protocols such as Bluetooth™, Bluetooth™ LE, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

Computing device 201 also may include a memory 202. Memory 202 may comprise a storage system configured to store a database 214 and an application 216. Application 216 may include instructions which, when executed by a processor 204, cause computing device 201 to perform various steps and/or functions, as described herein. Application 216 further includes instructions for generating a user interface 218 (e.g., graphical user interface (GUI)). Database 214 may store various algorithms and/or data, including neural networks (e.g., encoding flight policies, as described herein) and data regarding wind patterns, weather forecasts, historical and expected sunrise and sunset times, past and present locations of aerial vehicles (e.g., aerial vehicles 120a-b), sensor data, map information, air traffic information, among other types of data. Memory 202 may include any non-transitory computer-readable storage medium for storing data and/or software that is executable by processor 204, and/or any other medium which may be used to store information that may be accessed by processor 204 to control the operation of computing device 201.

Computing device 201 may further include a display 206, a network interface 208, an input device 210, and/or an output module 212. Display 206 may be any display device by means of which computing device 201 may output and/or display data. Network interface 208 may be configured to connect to a network using any of the wired and wireless short range communication protocols described above, as well as a cellular data network, a satellite network, free space optical network and/or the Internet. Input device 210 may be a mouse, keyboard, touch screen, voice interface, and/or any or other hand-held controller or device or interface by means of which a user may interact with computing device 201. In some examples, input device 201 may be used to apply flight tags (i.e., a flight engineer may tag a flight, for example, to selectively enable and/or disable certain commands, to enable and/or disable automated command sending while flight engineering is responding to an emergency, and other types of tags). In other examples, inputs to computing device 201 may be received from software and other programmed sources (e.g., configurations enabling and/or disabling command sending based on a software release for a flight, tweaking a duration that a subsystem is in one or more modes (e.g., any of the power saving modes described herein), and other configurations). Output module 212 may be a bus, port, and/or other interface by means of which computing device 201 may connect to and/or output data to other devices and/or peripherals.

In some examples computing device 201 may be located remote from an aerial vehicle (e.g., aerial vehicles 120a-b) and may communicate with and/or control the operations of an aerial vehicle, or its control infrastructure as may be housed in avionics chassis 110a-b, via a network. In one embodiment, computing device 201 is a data center or other control facility (e.g., configured to run a distributed computing system), and may communicate with a controller and/or flight computer housed in avionics chassis 110a-b via a network. As described herein, system 200, and particularly computing device 201, may be used for planning a flight path or course for an aerial vehicle based on wind and weather forecasts to move said aerial vehicle along a desired heading or within a desired radius of a target location. Various configurations of system 200 are envisioned, and various steps and/or functions of the processes described below may be shared among the various devices of system 200 or may be assigned to specific devices.

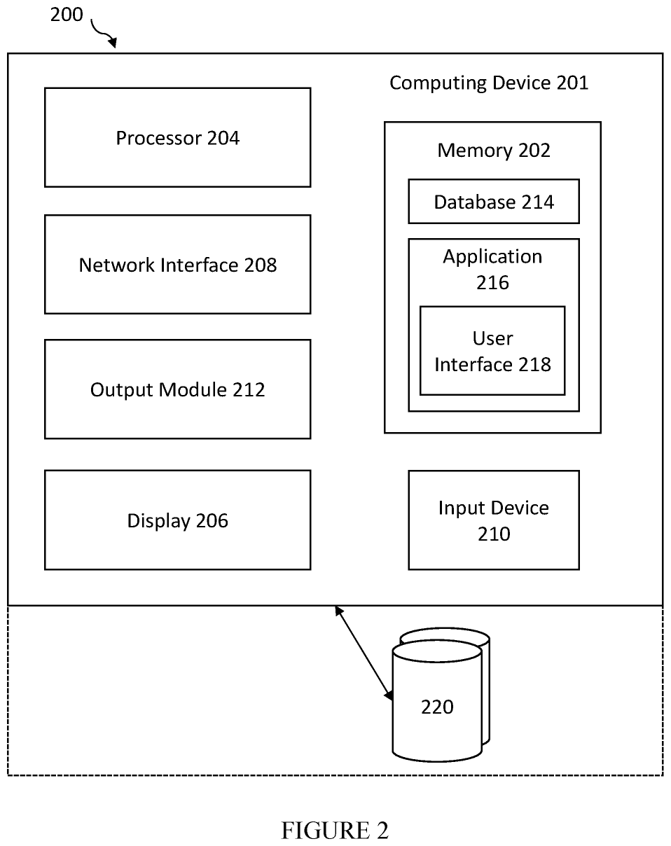

FIG. 3 is a simplified block diagram of an exemplary communications unit implemented onboard an aircraft, in accordance with one or more embodiments. Diagram 300 includes communications unit 310 and user devices 322. Communications unit 310 may include integrated circuit (“IC”) 312, one or more radio (“RF”) heads 320a-n, and heating component 324. In some examples, communications unit 310 may comprise an LTE eNodeB, and IC 312 may comprise an eNodeB baseband processor and may be implemented as a system on chip (SoC), network on chip (NoC), or other chip design. In some examples, IC 312 may include hardware controller 314 and processors 316-318. Processors 316-318 may comprise a high level monitoring processor (e.g., a general purpose CPU) and an LTE stack software processor (e.g., DSP). Hardware controller 314 may comprise low level hardware logic (e.g., FPGA) configured to access stored power from a power source (e.g., battery on an aerial vehicle), and control power to IC 312 and components thereof, as well as heating component 324 and RF heads 320a-n. RF heads 320a-n may be configured to transmit and receive radio waves (e.g., to communicate with cellular devices). User devices 322 may include a cellular phone, tablet computer, smart phone, desktop computer, laptop computer, and/or any other computing device known to those skilled in the art. In other examples, communications unit 310 may include laser or other light transmitters and receivers (not shown), in addition to or instead of RF heads 320a-n.

Heating component 324 may be configured to apply heat to one or more components of IC 312, for example, to prevent IC 312 or components thereof from damage caused by exposing it to temperatures below the storage specifications recommended by the manufacturer (i.e., a minimum viable temperature). In some examples, IC 312 and all of its components may have the same minimum viable temperature. In other examples, one or more component of IC 312 may have a different minimum viable temperature. In some examples, heating component 324 may be implemented on IC 312. In other examples, heating component 324 may comprise a separate component (not shown) configured to apply heat to IC 312. Hardware controller 314 may be configured to control power to heating component 324, for example, to turn heating component 324 on and off, and in some instances, to vary an intensity level of heating component 324.

In other examples, communications unit 310 may include, or be coupled to, a temperature sensor (not shown), which may be monitored by hardware controller 314 to determine whether and when heating component 324 should be turned on and off.

FIG. 4 is a simplified block diagram of an exemplary network comprising an exemplary communications unit, in accordance with one or more embodiments. Network 400 may include communications units 310 and 410, user devices 322, cellular network 430, and ground station 424. Communications units 310 and 410 may be implemented on an aerial vehicle (e.g., aerial vehicles 120a-b) and operate similarly to communications units 111a and 111b and each may include some or all of the components of communications unit 310 shown in FIG. 3 (e.g., hardware controller, processors). Cellular network 430 may comprise a wireless network configured to link and transfer data between nodes according to one or more standards (e.g., LTE or other wireless broadband standard).

Ground station 424 may include an always-on or fixed location computing device (i.e., capable of receiving fixed broadband transmissions), a ground terminal (e.g., ground station 114), and/or any other fixed or portable ground infrastructure for receiving and transmitting various modes of connectivity described herein and known to those skilled in the art. Communications units 310 and 410 may be capable of transmitting and receiving data signals (e.g., through radio waves, free space optics, or other means) to and from user devices 322 and ground station 424, directly or indirectly (e.g., through cellular network 430). In some examples, communications units 310 and 410 may be configured to transmit and receive data signals to and from each other. In some examples, communications units 310 and 410 may be capable of both connecting to the core network (e.g., Internet and core cellular data network), as well as delivering connectivity to each other, to user devices 322, and other facilities and vehicles. For example, communications units 310 and 410 may be configured to transmit and receive data signals to satellites, offshore industrial facilities (e.g., wind farms, oil rigs and wells), commercial transport (e.g., container ships, other cargo ships, tankers, other merchant ships, ferries, cruise ships, other passenger ships), and other vehicles on land, air, and sea.

In some examples, ground station 424 may provide core network functions, such as connecting to the Internet and core cellular data network (e.g., connecting to LTE EPC or other communications platforms, and a software defined network system) and performing mission control functions.

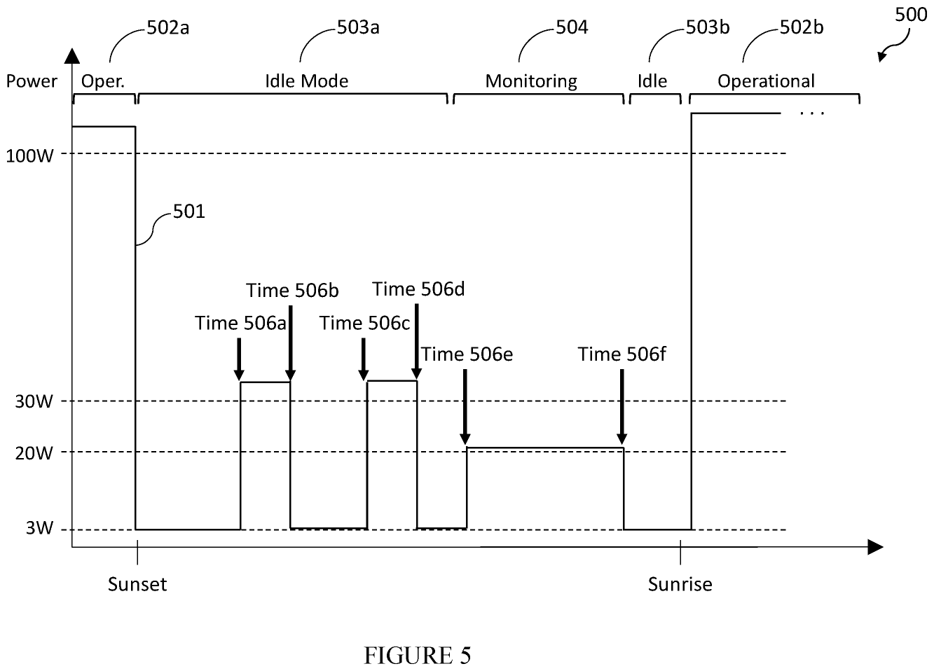

FIG. 5 is a chart showing exemplary power provided to a communication subsystem of a solar-powered aircraft in several power modes, in accordance with one or more embodiments. Chart 500 shows power levels (e.g., as controlled by hardware controller 314) for a subsystem (e.g., communications unit 310, communications unit 410, and the like) on the y-axis, and relative time on the x-axis, starting just before sunset until just after sunrise. Power levels (e.g., drawn, consumed, provided) are shown during various modes, including operational modes 502a-b, idle (“preservation”) modes 503a-b, and monitoring mode 504.

In operational modes 502a-b, most or all of the operational components of the subsystem (e.g., radio or optical transmitters, receivers, transceivers) are powered, and a high level of power (e.g., approximately or over 100 W) is being consumed. In some examples, there may be various high levels of power provided and consumed depending on the type(s) and number of operational components being powered.

In monitoring mode 504, a processor (e.g., one or both of processors 316-318, or other FPGA) may be powered at a moderate level (e.g., approximately 20 W-100 W, or more or less), sufficient to gather and transmit state and/or telemetry data and to receive commands. For example, in a monitoring mode, a high level FPGA may be powered at 20 W-30 W to monitor a state of the subsystem, generate state data to communicate with other onboard systems and offboard systems (e.g., LTE network, data center, and the like), and receive higher level commands from said onboard and offboard systems. In some examples, the start time 506e and end time 506f of monitoring mode 504 may be predetermined (e.g., periodically, given an amount of time since the last set of state data was published or communicated off board, or scheduled, such as at a given amount of time before a sunrise, a given amount of time after a sunset, or other schedule). The length of time in which a processor may be powered during a monitoring mode also may be predetermined. In other examples, time 506e may be determined dynamically, for example in response to a request from another onboard subsystem or offboard system. In still another example, the duration of monitoring mode 504 (e.g., period between time 506e and 5060 also may be determined dynamically (e.g., when all monitoring mode tasks have been completed).

In idle modes 503a-b, all or almost all components of the subsystem other than the hardware controller may be off, and a minimum power level (e.g., within a range of 3 W-30 W, or more or less) may be maintained so that the hardware controller may monitor at least a temperature sensor to assess if and when a heater should be turned on. For example, hardware controller 314 may be powered at approximately 3 W during idle modes 503a-b, sufficient to determine when to turn on (i.e., power) heating component 324, processor 316 and/or 318 (e.g., to enter a monitoring mode), one or more of RF heads 320a-n or other transceiver (e.g., radio or optical). In some examples, a heater may be turned on by a hardware controller during idle modes 503a and/or 503b to prevent the subsystem, or component thereof, from falling below a minimum viable temperature (e.g., predetermined at a temperature between 32° F. and −40° F.). For example, in an idle mode, hardware controller 314 may be configured to detect a temperature of one or more components of a subsystem (e.g., communications units 310 and/or 410) falling near, at, or below a minimum viable temperature and to turn on heating component 324. In this example, such detection may occur at or directly prior to time 506a, thereby causing hardware controller 314 to power on heating component 324 at time 506a for a period of time (e.g., between times 506a-b and/or times 506c-d). In another example, time 506a may be predetermined based on known data (e.g., historical, testing, derived) and through modeling, simulations, statistical analysis or other techniques for determining a time to turn on a heating component (e.g., before a subsystem or component breaks, minimizing power consumption without breaking the subsystem or a component).

In some examples, the length of time in which a heating component is turned on (e.g., time 506a to time 506b and time 506c to time 506d) may be predetermined based on known data (e.g., historical, testing, derived) and through modeling, simulations, statistical analysis or other techniques for determining an amount of heating time for which there is a high probability that a given heating component will bring a given subsystem or component up to a given temperature (i.e., a higher threshold temperature with a buffer above the minimum viable temperature), or otherwise optimized to balance power consumption with subsystem temperature. In other examples, the length of time in which a heating component is turned on (e.g., time 506a to time 506b and time 506c to time 506d) may be dynamic, and a heating component may be turned off once a hardware controller determines that a higher threshold temperature has been reached (e.g., by monitoring a temperature sensor on or electrically coupled to the subsystem or component.

Example Methods

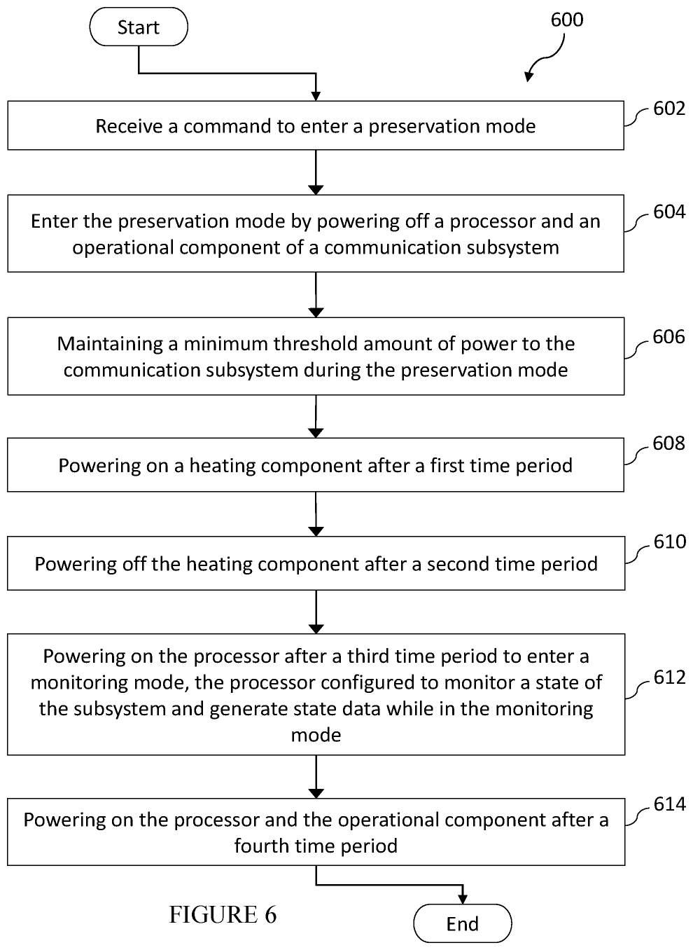

FIG. 6 is a flow diagram illustrating a method for implementing one or more power saving modes in a communication subsystem of a solar-powered aircraft, in accordance with one or more embodiments. Method 600 may begin by receiving a command, for example by a hardware controller, to enter a preservation (i.e., idle) mode at step 602. In some examples, the command may be received from a high level processor (e.g., on chip or otherwise onboard) or from an offboard system (e.g., offboard controller). For example, a high level processor implemented on the same integrated circuit as the hardware controller may be configured to instruct the hardware controller on timing and/or conditions for entering and exiting a preservation mode, entering and exiting a monitoring mode, and entering and exiting an operational mode. As mentioned above, such timing and conditions may be based on rules or may be dynamically determined in response to actual events (e.g., a sunset, a completion of one or more tasks, a sensor reading reaching a threshold). In another example, an offboard controller may be configured to send a command to a hardware controller to enter a preservation mode (e.g., at the same time every day, at a given time depending on location and altitude, a certain amount of time before, at, or after, a sunset or after a loss of solar power) and to exit a preservation mode (e.g., at the same time every day, at a given time depending on location and altitude, a certain amount of time before, at, or after, a sunrise, when battery power reaches a minimum threshold). At step 604, the hardware controller may enter (i.e., place the subsystem in) the preservation mode by powering off a processor (e.g., one or both of processors 316-318) and an operational component (e.g., one or more of RF heads 320a-n, or other transceiver, as described herein) of a communication subsystem. A minimum threshold amount of power to the communication subsystem may be maintained by the hardware controller during the preservation mode at step 606. A heating component may be powered on after a first time period at step 608. The first time period commences at or before a minimum viable temperature (e.g., temperature at which a subsystem or one of its components will suffer irreversible damage) is reached. At step 610, the heating component may be powered off after a second time period. As described herein, the first and the second time periods may be predetermined or may be dynamically determined. For example, a feedback loop may be implemented such that when a temperature sensor detects the subsystem temperature to be too cold (e.g., below a minimum viable temperature or other temperature threshold), the heaters are powered on (e.g., by a hardware controller), and when the temperature sensor detects the subsystem temperature to be too hot (e.g., at or above a higher threshold temperature), the heaters are powered off. The second time period is long enough for a given heating component to heat the subsystem to a higher threshold temperature, which may be set sufficiently higher than a minimum viable temperature to provide a desired buffer, such that the heaters do not need to be powered on too often or at all for the remainder of a night. In some examples, the second time period may occur while still in the preservation mode. In other examples, a separate mode may be defined for when the heating component is on.

At step 612, the processor may be powered on after a third time period to enter a monitoring mode, the processor configured to monitor a state of the subsystem and generate state data while in the monitoring mode. The hardware controller may enable a moderate amount of power to be provided to the processor during the monitoring mode. In some examples, the processor powered off at step 604 may comprise more than one type of processor, and at step 612, the hardware controller may power on one type, or more than one type, as needed to perform monitoring mode functions. In some examples, there may be automation configured in the subsystem, other onboard system, or offboard system (e.g., datacenter, controller) to send a command to the subsystem (e.g., to a hardware controller) to place the subsystem in a monitoring mode.

The processor and the operational component may be powered on after a fourth time period at step 614, for example to enter or return to an operational mode. In some examples, other modes may occur between or among the time periods described in method 600 (e.g., a return to idle mode during the fourth time period or between the third time period and the fourth time period, a separate heating mode during or between any of described time periods). In some examples, there may be automation configured in the subsystem, other onboard system, or offboard system (e.g., datacenter, controller), to send a command to place the subsystem in idle mode. When this command is sent, some or all of steps 602-612 may be executed. The subsystem (e.g., a hardware controller, a processor, and/or another component) may be configured to try to connect with a datacenter (e.g., an LTE management service run in the datacenter) to determine whether to begin transmitting (e.g., entering an operational mode) when a flight enters, or determines that it is in, a service region or location (i.e., wherein connectivity services are requested or desired). If the datacenter, or LTE management service being run therein, includes a communications configuration (e.g., an LTE config file or instruction describing frequencies at which to transmit, among other things), the subsystem may begin transmitting to users (e.g., entering an operational mode at step 614).

While specific examples have been provided above, it is understood that the present invention can be applied with a wide variety of inputs, thresholds, ranges, and other factors, depending on the application. For example, the time frames and ranges provided above are illustrative, but one of ordinary skill in the art would understand that these time frames and ranges may be varied or even be dynamic and variable, depending on the implementation.

As those skilled in the art will understand, a number of variations may be made in the disclosed embodiments, all without departing from the scope of the invention, which is defined solely by the appended claims. It should be noted that although the features and elements are described in particular combinations, each feature or element can be used alone without other features and elements or in various combinations with or without other features and elements. The methods or flow charts provided may be implemented in a computer program, software, or firmware tangibly embodied in a computer-readable storage medium for execution by a general-purpose computer or processor.

Examples of computer-readable storage mediums include a read only memory (ROM), random-access memory (RAM), a register, cache memory, semiconductor memory devices, magnetic media such as internal hard disks and removable disks, magneto-optical media, and optical media such as CD-ROM disks.

Suitable processors include, by way of example, a general-purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, or any combination of thereof.

What is claimed is:

1. An onboard subsystem of an aircraft comprising:
a first processor configured to monitor a state of the subsystem and generate state data;
a heating component configured to heat the subsystem to at least a minimum viable temperature;
an operational component; and
a hardware controller configured to control power to the heating component, the first processor, and the operational component, at least during a preservation mode and a monitoring mode,
wherein the subsystem draws a first moderate amount of power when the heating component is on and a minimum threshold amount of power in the preservation mode,
wherein the subsystem draws a second moderate amount of power in the monitoring mode in order to generate and communicate state data by the first processor, and
wherein the first and second moderate amounts of power are lower than a high amount of power required to operate the operational component.

2. The subsystem of claim 1, wherein the subsystem comprises a communications unit.

3. The subsystem of claim 2, wherein the communications unit comprises an LTE eNodeB.

4. The subsystem of claim 1, wherein the first processor comprises a high-level FPGA.

5. The subsystem of claim 1, further comprising a second processor configured to implement a software stack.

6. The subsystem of claim 1, wherein the operational component comprises a radio head configured to transmit and receive radio waves.

7. The subsystem of claim 1, wherein the first processor and the hardware controller are implemented as a system on chip.

8. The subsystem of claim 1, wherein the hardware controller is configured to receive a command from the first processor to control power to the first processor during the preservation mode.

9. The subsystem of claim 1, wherein the hardware logic is configured to monitor a temperature sensor in the preservation mode.

10. The subsystem of claim 1, wherein the hardware logic is configured to power on the heating component to the first moderate amount of power in response to a temperature sensor reading below a minimum viable threshold temperature.

11. The subsystem of claim 1, wherein the minimum threshold amount of power is within a range of 3 W-30 W.

12. The subsystem of claim 1, wherein the first moderate amount of power and the second moderate amount of power are both within a range of 20 W-100 W, the first moderate amount of power being higher than the second moderate amount of power.

13. A method for implementing one or more power saving modes in a communication subsystem of a solar-powered aircraft, the method comprising:
receiving, by a hardware controller, a command to enter a preservation mode;
entering the preservation mode by powering off, by the hardware controller, a processor and an operational component of the communication subsystem;
maintaining a minimum threshold amount of power to the communication subsystem during the preservation mode;
powering on, by the hardware controller, a heating component after a first time period;
powering off, by the hardware controller, a heating component after a second time period;
powering on, by the hardware controller, the processor after a third time period to enter a monitoring mode, the processor configured to monitor a state of the communication subsystem and generate state data while in the monitoring mode; and
powering on, by the hardware controller, the processor and the operational component after a fourth time period to return to an operational mode.

14. The method of claim 14, wherein the first period of time, the second period of time, and the third period of time, are predetermined.

15. The method of claim 14, wherein powering on the heating component occurs in response to a temperature sensor measuring below a minimum viable threshold temperature, the temperature sensor configured to measure a temperature of a circuit board on which the processor and the hardware controller are implemented.

16. The method of claim 14, wherein powering off the heating component occurs in response to a temperature sensor registering above a higher threshold temperature, the temperature sensor configured to measure a temperature of a circuit board on which the processor and the hardware controller are implemented.

17. The method of claim 14, wherein the state data generated in the monitoring mode comprises sensor data.

18. The method of claim 14, wherein the state data generated in the monitoring mode comprises a time elapsed in the preservation mode.

19. The method of claim 14, wherein the state data generated in the monitoring mode comprises a time elapsed since the processor last broadcasted a set of state data in the monitoring mode.

20. The method of claim 14, wherein the state data generated in the monitoring mode comprises a time elapsed since a last sunset.

21. The method of claim 14, wherein the state data comprises a next expected sunrise time.

22. The method of claim 14, wherein the operational component comprises a radio head configured to transmit and receive radio waves.

23. The method of claim 14, wherein the communication subsystem is a non-flight critical component of the solar-powered aircraft.

24. The method of claim 14, wherein receiving the command to enter the preservation mode occurs shortly before, at, or after, a sunset.

25. The method of claim 14, wherein powering on the processor and the operational component after a fourth period of time to return to an operational mode occurs after a sunrise.
